(19) United States
(12) Patent Application Publication
(10) Pub. No.: US 2013/0104006 A1
(43) Pub. Date: Apr. 25, 2013

(54) APPARATUS AND METHOD FOR TRANSMITTING DATA IN COMMUNICATION SYSTEM

(71) Applicant: Electronics and Telecommunications Research Institute, Daejeon (KR)

(72) Inventors: Seung-Han CHOI, Daejeon (KR); Do-Young KIM, Daejeon (KR); Byung-Sun LEE, Daejeon (KR)

(73) Assignee: Electronics and Telecommunications Research Institute, Daejeon (KR)

(21) Appl. No.: 13/653,879

(22) Filed: Oct. 17, 2012

(30) Foreign Application Priority Data
Oct. 17, 2011 (KR) 10-2011-0106060
Oct. 16, 2012 (KR) 10-2012-0114719

(51) Int. Cl. H03M 13/05

(52) U.S. Cl. CPC H03M 13/05
USPC 714/776; 370/310

(57) ABSTRACT

Disclosed are an apparatus and a method for transmitting data so as to maximally recover lost data packets by a forward error correction (FEC) scheme in a wireless communication based internet protocol (IP) network. The apparatus for transmitting data confirms a state of data samples according to data patterns of data patterns to be transmitted through a wireless channel, calculates state probabilities of the data samples according to the state of the data samples, determines the generation of redundant data packets of the data packets based on the state probabilities of the data samples, generates the redundant data packets using the data packets according to the determination of the generation of the redundant data packets, and transmits the data packets and the redundant data packets through the wireless channel.

### CROSS-REFERENCES TO RELATED APPLICATIONS

The present application claims priority of Korean Patent Application Nos. 10-2011-0106060 and 10-2012-0114719, filed on Oct. 17, 2011, and Oct. 16, 2012, respectively, which are incorporated herein by reference in their entirety.

### BACKGROUND OF THE INVENTION

1. Field of the Invention

Exemplary embodiments of the present invention relate to an apparatus and a method for transmitting data so as to maximally recover lost data packets by a forward error correction (hereinafter, referred to as ‘FEC’) scheme in a wireless communication based internet protocol (hereinafter, referred to as ‘IP’) network.

2. Description of Related Art

In a current communication system, researches for providing services having various qualities of services (hereinafter, referred to as QoSs) to users at a high transmission rate have been actively conducted. The communication system has proposed methods for rapidly transmitting data having various types of QoSs through limited resources and has recently proposed methods for providing various multimedia services, such as voice, image, and the like, through a packet network with the development of a network and the increase in a user demand for a high-quality service.

Meanwhile, in the current communication system, at the time of transmitting and receiving a voice over IP (VoIP) packet through an IP packet network, voice information of the VoIP packet is transmitted and received through a user datagram protocol (UDP) layer. In this case, there is a limitation in stably transmitting and receiving the VoIP packet according to the characteristics of the UDP. In particular, in the current communication system, when transmitting and receiving data packets corresponding to various multimedia services from and to user equipment through a wireless communication based wireless local area network (hereinafter, referred to as ‘WLAN’) and a mobile communication network, that is, a wireless channel, the data packets transmitted and received from and to the user equipment are lost due to an increase in a variable bandwidth of a wireless channel and a bit error rate of the wireless channel, a transmission delay of data packets due to a movement of user equipment, and the like.

Further, in the current communication system, there have been proposed methods for recovering data packets lost as described above. For example, in order for an apparatus for receiving data packets to recover lost data packets by the FEC scheme, an apparatus for transmitting the data packets generates redundant data packets based on the data packets to be transmitted and transmits the data packets and the redundant data packets and the receiving apparatus recovers the lost data packets based on the FEC scheme using the received redundant data packets and data packets to normally receive the data packets transmitted from the transmitting apparatus.

However, in the current communication system, when recovering the lost data packets by the FEC scheme, the receiving apparatus requests the transmission of the redundant data packets to the transmitting apparatus in consideration of the loss of the data packets and recovers the lost data packets by the FEC scheme using the received redundant data packets in correspondence with the request of the redundant data packets, such that there are limitations in recovering performance, recovering rate, and the like, of the lost data packets.

In particular, in the current communication system, as the receiving apparatus requests the transmission of the redundant data packets for recovering the data packets lost in the wireless channel in correspondence with the generation of the lost data packets to the transmission apparatus when the loss of the data packets occur in the wireless channel, a large amount of data packets may be lost in advance until the lost data packets are recovered using the redundant data packets and the service quality may be remarkably degraded when the data packets are continuously lost in the wireless channel.

Therefore, in the communication system, when the data packets are transmitted and received through, for example, the wireless communication based IP network, that is, the wireless channel, a need exists for a data transmitting method for stably transmitting and receiving large-capacity data while improving the quality of service so that the receiving apparatus recovers the lost data packets fast and maximally by the FEC scheme.

### SUMMARY OF THE INVENTION

An embodiment of the present invention is directed to provide an apparatus and a method for transmitting data in a communication system.

Another embodiment of the present invention is directed to provide an apparatus and a method for transmitting data so as to maximally recover lost data packets by a forward error correction (FEC) scheme, at the time of transmitting and receiving data packets using a wireless communication based internet protocol (IP) network in a communication system.

A still another embodiment of the present invention is directed to provide an apparatus and a method for transmitting data so as to maximally recover lost data packets by a forward error correction scheme, by confirming a loss of data packets occurring at the time of transmitting and receiving the data packets through a wireless channel in a communication system based on an analysis of data patterns of the data packets to be transmitted.

The foregoing and other objects, features, aspects and advantages of the present invention will be understood and become more apparent from the following detailed description of the present invention. Also, it can be easily understood that the objects and advantages of the present invention can be realized by the units and combinations thereof recited in the claims.

An apparatus for transmitting data in a communication system includes: a detection unit configured to confirm a state of data samples according to data patterns of data packets to be transmitted through a wireless channel; a selection unit configured to calculate a state probability of the data samples according to the state of the data samples and determine a generation of redundant data packets of the data packets based on the state probability of the data samples; a forward error correction (FEC) module configured to use the data packets according to the determination of the generation of the redundant data packets to generate the redundant data packets; and an interface module configured to transmit the data packets and the redundant data packets through the wireless channel.

A method for transmitting data in a communication system, includes: confirming a state of data samples according to data patterns of data packets to be transmitted through a wireless channel; calculating state probabilities of the data samples according to the state of the data samples and determining a generation of redundant data packets of the data packets based on the state probability of the data samples; generating the redundant data packets using the data packets according to the determination of the generation of the redundant data packets; and transmitting the data packets and the redundant data packets through the wireless channel.

### BRIEF DESCRIPTION OF THE DRAWINGS

FIG. 1 is a diagram for describing an analysis of data patterns of data packets in a communication system in accordance with an embodiment of the present invention.

FIG. 2 is a diagram schematically illustrating data samples according to data patterns of data packets in the communication system in accordance with the embodiment of the present invention.

FIG. 3 is a diagram schematically illustrating a structure of a transmitting apparatus in a communication system in accordance with an embodiment of the present invention.

FIG. 4 is a diagram schematically illustrating an operation of a transmitting apparatus in a communication system in accordance with the embodiment of the present invention to generate redundant data packets.

FIG. 5 is a diagram for describing a state probability calculation of data packets when a transmitting apparatus in the communication system in accordance with the embodiment of the present invention generates redundant data packets.

### DESCRIPTION OF SPECIFIC EMBODIMENTS

Hereinafter, embodiments of the present invention will be described in detail with reference to the accompanying drawings. It is to be noted that only components required to understand an operation in accordance with the present invention is described below and the description of other components will be omitted not to unnecessarily obscure the subject matters of the present invention.

The present invention proposes an apparatus and a method for transmitting data that transmit data packets through a communication system, for example, a wireless communication based Internet protocol (hereinafter, referred to as ‘IP’) network, a wireless channel, and the like. Here, although the embodiment of the present invention describes, by way of example, a communication system including a wireless communication based IP network, for example, a wireless local area network (hereinafter, referred to as ‘WLAN’) system, a method for transmitting data proposed in the present invention may also be applied to other communication systems. Further, although the embodiment of the present invention describes, by way of example data packets corresponding to various multimedia services, such as voice, image, and the like, in particular, voice data packets corresponding to voice services, for convenience of explanation, the present invention may also be applied to transmission and reception of data corresponding to other service types, that is, services having various qualities of services (hereinafter, referred to as ‘QoSs’).

Further, in the embodiment of the present invention, the data packets are transmitted so as to maximally recover lost data packets by a forward error correction (hereinafter, referred to as ‘FEC’), by confirming a loss of the data packets occurring at the time of transmitting and receiving the data packets through a wireless channel in a communication system based on an analysis of patterns of the data packets. Here, the communication system in accordance with the embodiment of the present invention confirms the loss of the data packets occurring at the time of transmitting and receiving the data packets using the wireless communication based IP, that is, the wireless channel based on an analysis of the patterns of the data packets to be transmitted to generate the redundant data packets and transmits the data packets and the redundant data packets to allow the receiving apparatus of the data packets to recover the lost data packets fast and maximally by the FEC scheme, thereby stably transmitting and receiving large-capacity data while improving a quality of service.

In this case, in the communication system in accordance with the embodiment of the present invention, the transmitting apparatus analyzes the data patterns of the data packets to be transmitted, for example, the data patterns of the voice data packets to confirm the redundant data packets corresponding to the loss of the data packets and generates the redundant data packets corresponding to the loss of the redundant data packets and then transmits the data packets and the redundant data packets to the receiving apparatus and the receiving apparatus recovers the lost data packets fast and maximally using the data packets and the redundant data by the FEC scheme, thereby stably transmitting and receiving the large-capacity data.

Here, in the communication system in accordance with the embodiment of the present invention, the receiving apparatus analyzes the loss of the data packets not to determine the generation of the redundant data packets for recovering the lost data packets by the FEC scheme and the transmitting apparatus for transmitting the data packets analyzes the data packets for the data packets, for example, the voice patterns of the voice data packets to determine the generation of the redundant data packets for recovering the lost data packets by the FEC scheme. That is, in the communication system in accordance with the embodiment of the present invention; as described above, the transmitting apparatus analyzes the data patterns of the data packets to determine the generation of the redundant data packets and generates the determined redundant data packets and transmits the generated redundant data packets along with the data packets to the receiving apparatus and the receiving apparatus recovers the lost data packets using the received redundant data packets and data packets by the FEC scheme.

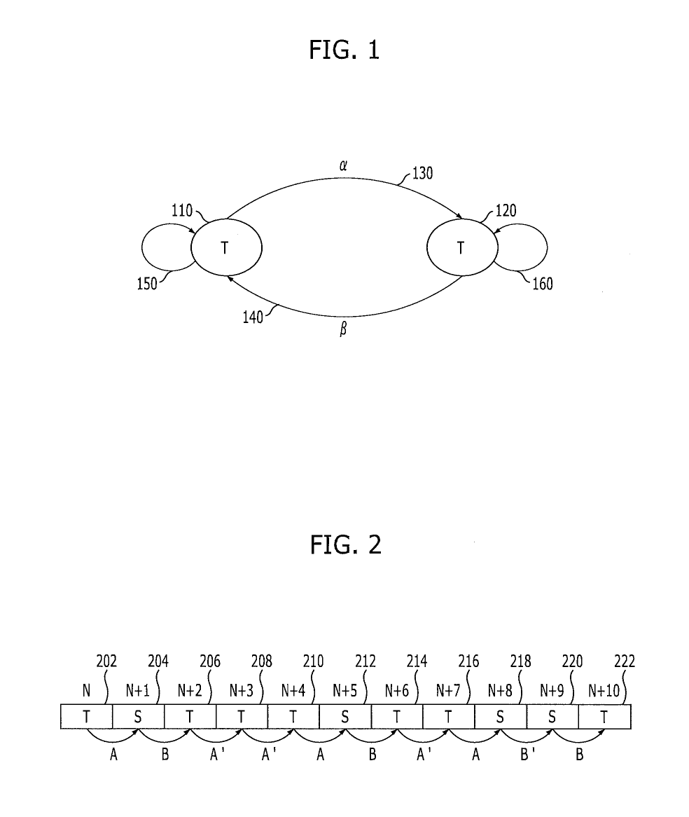

In other words, in the existing communication system, the receiving apparatus requests the transmission of the redundant data packets to the transmitting apparatus by analyzing a loss rate of the data packets in the wireless channel or the wireless link so as to recover the lost data packets by the FEC scheme and then recovers the lost data packets by the FEC scheme using the transmitted data packets and redundant data packets transmitted from the transmitting apparatus according to the request, but in the communication system in accordance with the embodiment of the present invention, the transmitting apparatus analyzes the data patterns of the data packets to determine the generation of the redundant data packets for recovering the lost data packets by the FEC scheme and transmits the generated redundant data packets along with the data packets to the receiving apparatus and the receiving apparatus recovers the lost data packets fast and maximally using the received redundant data packets and data packets by the FEC scheme. Therefore, the communication system in accordance with the embodiment of the present invention minimizes the loss of the data packets occurring at the time of transmitting and receiving the data packets through the wireless channel or the wireless link and recovers the lost data packets fast, thereby improving the quality of service and stably transmitting and receiving the large-capacity data. Hereinafter, the analysis of the data patterns of data packets in the communication system in accordance with the embodiment of the present invention will be described in detail with reference to FIG. 1.

FIG. 1 is a diagram for describing the analysis for the data patterns of the data packets in the communication system in accordance with an embodiment of the present invention. Here, FIG. 1 is a diagram illustrating a voice state according to the data patterns of the data packets, for example, the voice patterns of the voice data packets and is a diagram illustrating a voice state machine analyzed by analyzing the voice pattern based on a two-state Markov chain.

Referring to FIG. 1, in the communication system, the voice pattern of the voice data packet includes a first state T 110 indicating a state in which a speaker generating voice data generates the voice data, that is, a state in which a speaker speaks and a second state S 120 indicating a state in which the speaker does not generate the voice data, that is, a state in which a speaker does not speak and includes a case 130 shifted from the first state 110 to the second state 120, a case 140 shifted from the second state 120 to the first state, a case 150 shifted from the first state 110 to the first state 110, and a case 160 shifted from the second state 120 to the second state 120.

Here, when the probability of the case 130 shifted from the first state 110 to the second state 120 is α, the probability α becomes Pr[Xn+1=T/Xn=S], when the probability of the case 140 shifted from the second state 120 to the first state is β, the probability β becomes Pr [Xn+1=S/Xn=T], and when the probability of the case 150 shifted from the first state 110 to the first state 110 becomes (1−α), and the probability of the case 160 shifted from the second state 120 to the second state 120 becomes (1−β).

Further, the probability of the case in which the voice packet for the voice data packet is the first state 110 becomes Pr [Xn=T]=β/(α+β) and the probability of the case in which the voice pattern of the voice data packet is the second state 120 becomes Pr [Xn=S]=α/(α+β). Hereinafter, the voice state probability calculation according to the data patterns of the voice data packets in the communication system in accordance with the embodiment of the present invention will be described in detail with reference to FIG. 2.

FIG. 2 is a diagram schematically illustrating data samples according to the data patterns of the data packets in the communication system in accordance with the embodiment of the present invention. Here, FIG. 2 is a diagram schematically illustrating an order of voice samples for a voice state probability calculation according to the data packets, for example, the voice patterns of the voice data packets as illustrated in FIG. 1.

Referring to FIG. 2, as the voice samples according to the voice patterns of the voice data packets in the communication system, voice samples 202, 206, 208, 210, 214, 216, and 222 in the first state T and voice samples 204, 212, 218, and 220 in the second state S sequentially exist from N-th to (N+10)-th.

In the voice samples from N-th to (N+10)-th as illustrated in FIG. 2, the number A of cases about the probability α, that is, the number A of cases about the probability α of the case shifted from the first state T to the second state S becomes 3, the number A′ of cases about the probability 1−α, that is, the number A′ of cases about the probability 1−α of the case in which the first state T is maintained becomes 3, the number B of cases about th probability β, that is, the number B of cases about the probability β of the case shifted from the second state S to the first state T becomes 3, and the number B′ of cases about the probability 1−β, that is, the number B′ of cases about the probability 1−β of the case in which the second state S is maintained becomes 1.

Therefore, in the communication system, the probability α of the voice sample, the probability β, the probability Pr [Xn=T]=β/(α+β), and the probability Pr [Xn=S]=α/(α+β) are calculated based on the number A of cases about the probability α, the number A′ of cases about the probability 1−α, the number B of cases about the probability β, the number B′ of cases about the probability 1−β. That is, in the communication system, the probability α of the case in which the voice sample is shifted from the first state T to the second state S, the probability β of the case in which the voice sample is shifted from the second state S to the first state T, the probability Pr [Xn=T]=β/(α+β) of the case in which the voice sample is the first state T, and the probability Pr [Xn=S]=α/(α+β) of the case in which the voice sample is the second state S are each calculated. For example, the probability α of the case in which the voice sample is shifted from the first state T to the second state S becomes A/(A+A′)=0.5, the probability β of the case in which the voice sample is shifted from the second state S to the first state T becomes B/(B+B′)=0.75, the probability Pr [Xn=T]=β/(α+β) of the case in which the voice sample is the first state T becomes 0.6, and the probability Pr [Xn=S]=α/(α+β) of the case in which the voice sample is the second state S becomes 0.4.

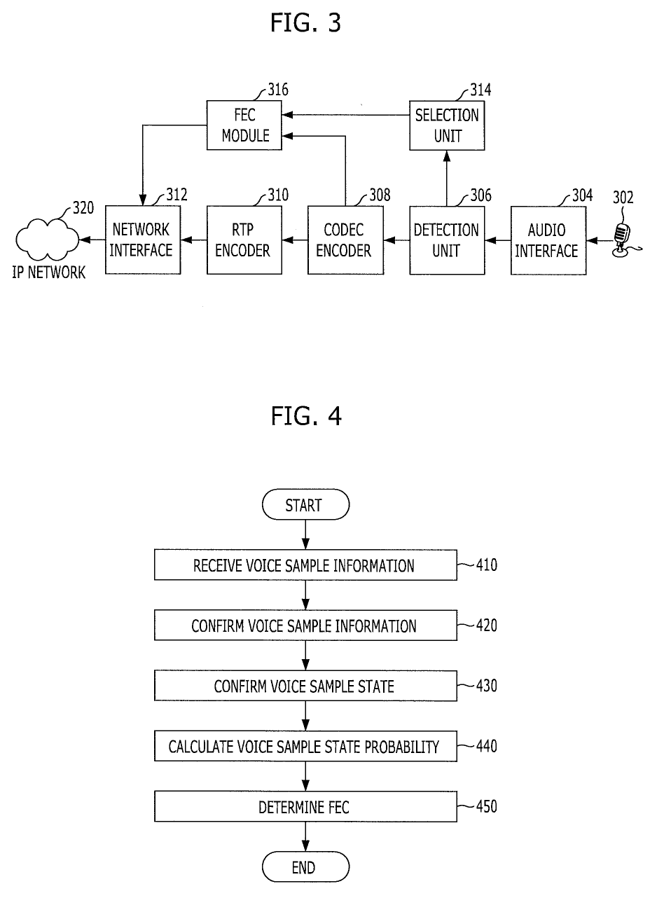

That is, in the communication system, as described above, the state probabilities of the data samples according to the data patterns of the data packets are calculated. In other words, in the communication system, the transmitting apparatus calculates the state probabilities of the data samples according to the data patterns of the data packets to analyze the data patterns of the data packets, analyzes the data patterns to determine the generation of the redundant data packets for recovering the lost data packets by the FEC scheme in the receiving apparatus and the transmitting apparatus transmits the redundant data packets and the data packets through the wireless channel or the wireless link and the receiving apparatus recovers the lost data packets using the received redundant data packets and data packets by the FEC scheme. Herein, the apparatus for transmitting data in the communication system in accordance with the embodiment of the present invention will be described in detail with reference to FIG. 3.

FIG. 3 is a diagram schematically illustrating a structure of the transmitting apparatus in the communication system in accordance with the embodiment of the present invention. Here, FIG. 3 is a diagram schematically illustrating a structure of the transmitting apparatus that analyzes the data packets, for example, the voice patterns for the voice data packets to generate the redundant data packet data and then transmits the redundant packet data and the voice data packets.

Referring to FIG. 3, the transmitting apparatus includes: a mike 302 configured to output voice data according to a state in which a speaker speaks or does not speak; an audio interface module 304 configured to output the voice data to the voice samples; a detection unit 306 configured to detect a sample state of the voice samples; a codec encoder 308 configured to encode the voice samples using a codec; an RTP encoder 310 configured to encode the encoded voice data into data packets, for example, real-time transport protocol (hereinafter, referred to as ‘RTP’) packets, a selection unit 314 configured to determine the generation of the redundant data packets for recovering the lost data packets by the FEC scheme in correspondence with the sample state; an FEC module 316 configured to generate the redundant data packets according to the determination of the generation of the redundant data packets; and a network interface module 312 configured to transmit the data packets and the redundant data packets to the receiving apparatus through an IP network 320.

Here, the detection unit 306 confirms the voice samples of the voice data input through the audio interface module 304, in particular, the state of the voice samples according to the voice patterns of the voice data, in other words, detects whether the voice sample is the first state T indicating the state in which the speaker speaks or the second state S indicating the state in which the speaker does not speak, as described in FIGS. 1 and 2. In addition, the detection unit 306 confirms whether the voice sample is a voice sample of the case shifted from the first state T to the second state S, the voice sample is a voice sample of the case shifted from the second state S to the first state T, and the voice sample is a voice sample of the case shifted from the first state T to the first state T or a voice sample of the case shifted from the second state S to the second state S, respectively.

Further, the selection unit 314 calculates the state probability of the voice sample according to the voice patterns of the voice data as illustrated in FIGS. 1 and 2. That is, as described above, the selection unit 314 calculates the probability α of the case in which the voice sample is shifted from the first state T to the second state S, the probability β of the case in which the voice sample is shifted from the second state S to the first state T, the probability Pr [Xn=T]=β/(α+β) of the case in which the voice sample is the first state T, and the probability Pr [Xn=S]=α/(α+β) of the case in which the voice sample is the second state S, respectively. The selection unit 314 calculating the state probabilities of the voice samples according to the voice patterns of the voice data determines the generation of the redundant data packets for recovering the lost data packets by the FEC scheme in the receiving apparatus based on the state probability.

Here, the selection unit 314 determines the generation of the redundant data packets in consideration of the loss rate of the data packets based on the state probabilities of the voice samples, for example, determines whether a small number of redundant data packets are generated according to the low loss rate of the data packets, a larger number of redundant data packets are generated according to the high loss rate of the data packets, or the redundant data packets are not generated. That is, the selection unit 314 determines the number of redundant data packets in consideration of the loss rate of the data packets in the wireless channel based on the state probabilities of the voice samples. Here, the data packets, for example, the state probability calculation of the voice samples according to the voice patterns of the voice data packets will be described above in detail, and therefore the detailed description thereof will be omitted.

The FEC module 316 generates the redundant data packets by using the voice data encoded by the codec encoder 308 according to the determination of the generation of the redundant data packets by the selection unit 314.

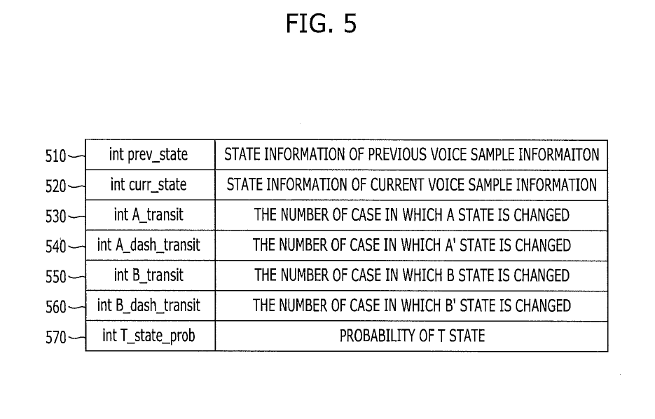

In addition, the network interface module 312 transmits the voice data packets and the redundant data packets to the receiving apparatus through the wireless communication based IP network 320, that is, the wireless channel or the wireless link and the receiving apparatus recovers the lost data packets using the received redundant data packets and data packets by the FEC scheme. Here, the operation of generating the redundant data packets for recovering the lost data packets by the FEC scheme in the communication system in accordance with the embodiment of the present invention will be described in more detail with reference to FIGS. 4 and 5.

FIG. 4 is a diagram schematically illustrating an operation of the transmitting apparatus in the communication system in accordance with the embodiment of the present invention to generate the redundant data packets and FIG. 5 is a diagram for describing the state probability calculation of the data packets when the transmitting apparatus in the communication system in accordance with the embodiment of the present invention generates the redundant data packets.

Referring to FIG. 4, in S410, the transmitting apparatus receives the data packets, for example, the information of the voice samples according to the voice patterns of the voice data packets and then, in S420, confirms the information of the received voice samples.

Next, in S430, it is confirmed whether the state of the voice sample is the first state T indicating the state in which a speaker speaks and the second state S indicating the state in which a speaker does not speak. That is, as described above, it is confirmed whether the voice sample is a voice sample of the case shifted from the first state T to the second state S, the voice sample is a voice sample of the case shifted from the second state S to the first state T, and the voice sample is a voice sample of the case shifted from the first state T to the first state T or a voice sample of the case shifted from the second state S to the second state S, respectively.

Here, in a data structure for the state probability calculation of the data packets illustrated in FIG. 5 according to the state of the confirmed voice samples, a variable int_prev_state 510 indicating the state information of previous voice sample information and a variable int_curr_state 520 indicating the state information of current voice sample information each store the number of confirmed cases.

Further, in S440, the state probabilities of the voice samples according to the voice patterns of the voice data are calculated. In other words, as described above, the probability α of the case in which the voice sample is shifted from the first state T to the second state S, the probability β of the case in which the voice sample is shifted from the second state S to the first state T, the probability Pr [Xn=T]=β/(α+β) of the case in which the voice sample is the first state T, and the probability Pr [Xn=S]=α/(α+β) of the case in which the voice sample is the second state S are each calculated.

In this case, the number A of cases about the probability α, that is, the number A of cases about the probability α of the case shifted from the first state T to the second state S, the number A′ of cases about the probability 1−α, that is, the number A′ of cases about the probability 1−α of the case in which the first state T is maintained, the number B of cases about the probability β, that is, the number B of cases about the probability β of the case shifted from the second state S to the first state T, the number B′ of cases about the probability 1−β, that is, the number B′ of cases about the probability 1−β of the case in which the second state S is maintained, and then in the data structure for the state probability calculation of the data packets illustrated in FIG. 5, each variable for the number of cases, that is, a variable int A_transit 530 indicating the number of cases in which the A state is changed, a variable int A_dash_transit 540 indicating the number of cases in which the A′ state is changed, a variable int B_transit 550 indicating the number of cases in which the B state is changed, and a variable int B_dash_transit 560 indicating the number of cases in which the B′ state is changed each store the number of confirmed cases.

The probability α, the probability β, and the probability Pr [Xn=T]=β/(α+β), and the probability Pr [Xn=S]=α/(α+β) of the voice samples according to the voice packets of the voice data packets are calculated based on the number A of cases about the probability α, the number A′ of cases about the probability 1−α, the number B of cases about the probability β, and the number B′ of cases about the probability 1−β. That is, in the communication system, the probability α of the case in which the voice sample is shifted from the first state T to the second state S, the probability β of the case in which the voice sample is shifted from the second state S to the first state T, the probability Pr [Xn=T]=β/(α+β) of the case in which the voice sample is the first state T, and the probability Pr [Xn=S]=α/(α+β) of the case in which the voice sample is the second state S are each calculated. Here, in the data structure for the state probability calculation of the data packets illustrated in FIG. 5, the probability Pr [Xn=T]=β/(α+β) of the case of the first state T is stored in a variable int T_state_prob 570 indicating the probability that a speaker is in a speaking state. Here, the data packets, for example, the state probability calculation of the voice samples according to the voice patterns of the voice data packets will be described above in detail, and therefore the detailed description thereof will be omitted.

Next, in S450, the FEC scheme in the receiving apparatus is determined in consideration of the loss rate of the data packets in the wireless channel based on the state probability of the voice samples. In other words, the voice patterns of the voice data packets are analyzed based on the state probabilities of the voice samples to determine the generation of the redundant data packets for recovering the lost data packets by the FEC scheme in the receiving apparatus in consideration of the voice patterns, that is, the loss rate of the data packets in the wireless channel or the wireless link based on the state probabilities of the voice samples. Here, it is determined whether a small number of redundant data packets are generated according to the low loss rate of the data packets, a large number of redundant data packets are generated according to the high loss rate of the data packets, or the redundant data packets are not generated.

In the communication system in accordance with the embodiment of the present invention, the transmitting apparatus calculates the state probabilities of the data samples according to the data patterns of the data packets to analyze the data patterns of the data packets and analyzes the data patterns to determine the generation of the redundant data packets for recovering the lost data packets by the FEC scheme in the receiving apparatus and the transmitting apparatus transmits the redundant data packets and the data packets through the wireless channel or the wireless link and the receiving apparatus recovers the lost data packets using the received redundant data packets and data packets by the FEC scheme.

The present invention confirms the loss of the data packets occurring at the time of transmitting and receiving the data packets using the wireless communication based internet protocol (IP) network, in other words, the wireless channel in the communication system by analyzing the data patterns of the data packets to be transmitted and generates the redundant data packets so as to be transmitted along with the data packets, such that the receiving apparatus of the data packets recovers the lost data packets fast and maximally by the forward error correction (FEC) scheme, thereby improving the quality of service and stably transmitting and receiving the large-capacity data.

Meanwhile, the embodiments is described in detail in the detailed description of the present invention, but may be variously modified without departing from the scope of the present invention. Accordingly, the scope of the present invention is not construed as being limited to the described embodiments but is defined by the appended claims as well as equivalents thereto.

What is claimed is:

1. An apparatus for transmitting data in a communication system, comprising:
a detection unit configured to confirm a state of data samples according to data patterns of data packets to be transmitted through a wireless channel;
a selection unit configured to calculate state probabilities of the data samples according to the state of the data samples and determine a generation of redundant data packets of the data packets based on the state probability of the data samples;
a forward error correction (FEC) module configured to use the data packets according to the determination of the generation of the redundant data packets to generate the redundant data packets; and
an interface module configured to transmit the data packets and the redundant data packets through the wireless channel.

2. The apparatus of claim 1, further comprising:
a receiver configured to recover lost data packets using the data packets and the redundant data packets received through the wireless channel by a forward error correction scheme.

3. The apparatus of claim 1, wherein the selection unit confirms the number of cases about state probabilities of the data samples from the state of the data samples and then uses the number of cases about the state probabilities of the data samples to calculate the state probabilities of the data samples.

4. The apparatus of claim 3, wherein the selection unit determines the number of redundant data packets in consideration of a loss rate of the data packets in the wireless channel based on the state probabilities of the data samples.

5. The apparatus of claim 1, wherein the detection unit confirms the voice samples according to the voice patterns of the voice data packets when the data packets are the voice data packets.

6. The apparatus of claim 5, wherein the detection unit confirms whether the voice samples are voice samples in a first state in which voice data are generated or whether the voice samples are voice samples in a second state in which the voice data are not generated.

7. The apparatus of claim 6, wherein the selection unit confirms the case in which the voice sample is shifted from the first state to the second state, the case in which the voice sample is shifted from the second state to the first state, the case in which the voice sample is shifted from the first state to the first state, and the case in which the voice sample is shifted from the second state to the second state, respectively.

8. The apparatus of claim 7, wherein the selection unit calculates the state probabilities of the voice samples for the respective shifted cases, respectively and determines the number of redundant data packets in consideration of the loss rate of the voice data packets in the wireless channel based on the state probabilities of the voice samples.

9. A method for transmitting data in a communication system, comprising:
confirming a state of data samples according to data patterns of data packets to be transmitted through a wireless channel;
calculating state probabilities of the data samples according to the state of the data samples and determining a generation of redundant data packets of the data packets based on the state probability of the data samples;
generating the redundant data packets using the data packets according to the determination of the generation of the redundant data packets; and
transmitting the data packets and the redundant data packets through the wireless channel.

10. The method of claim 9, further comprising:
recovering lost data packets using the data packets and the redundant data packets received through the wireless channel by a forward error correction (FEC) scheme.

11. The method of claim 9, wherein in the determining, the number of cases about state probabilities of the data samples is confirmed from the state of the data samples and the state probabilities of the data samples is calculated using the number of cases about the state probabilities of the data samples.

12. The method of claim 11, wherein in the determining, the number of redundant data packets is determined in consideration of a loss rate of the data packets in the wireless channel based on the state probabilities of the data samples.

13. The method of claim 9, wherein in the confirming, the voice samples are confirmed according to the voice patterns of the voice data packets when the data packets are the voice data packets.

14. The method of claim 13, wherein in the determining, it is confirmed whether the voice samples are voice samples in a first state in which voice data are generated or whether the voice samples are voice samples in a second state in which the voice data are not generated.

15. The method of claim 14, wherein in the determining, the case in which the voice sample is shifted from the first state to the second state, the case in which the voice sample is shifted from the second state to the first state, the case in which the voice sample is shifted from the first state to the first state, and the case in which the voice sample is shifted from the second state to the second state are each confirmed.

16. The method of claim 15, wherein in the determining, the state probabilities of the voice samples for the respective shifted cases are each calculated and the number of redundant data packets is determined in consideration of the loss rate of the voice data packets in the wireless channel based on the state probabilities of the voice samples.
